(19) United States
(12) Patent Application Publication
(10) Pub. No.: US 2007/0029631 A1
(43) Pub. Date: Feb. 8, 2007

(54) Package Structure and Wafer Level Package Method

(75) Inventor: Wei-Chung Wang, Kao-Hsiung Hsien (TW)

Correspondence Address: NORTH AMERICA INTELLECTUAL PROPERTY CORPORATION, P.O. BOX 506, MERRIFIELD, VA, 22116, US

(73) Assignee: ADVANCED SEMICONDUCTOR ENGINEERING, INC., Kao-Hsiung City (TW)

(21) Appl. No.: 11/275,256

(22) Filed: Dec. 21, 2005

(30) Foreign Application Priority Data
Aug. 2, 2005 (TW) 094126219

(51) Int. Cl. H01L 23/02; H01L 21/46

(52) U.S. Cl. 257/433; 438/455; 438/458; 257/678

(57) ABSTRACT

A wafer level package process includes: providing a device substrate, in which one surface of the device substrate includes a plurality of devices; providing a cap substrate and forming a plurality of cavities on one surface of the cap substrate, in which the location of each cavity is corresponding to the location of each device of the devices substrate; forming a protective cap in each cavity by utilizing the cavity as a mold; aligning each cavity of the cap substrate to each device of the device substrate and connecting the protective cap on the device substrate, such that each of the protective caps covers each device; and removing the cap substrate from the protective cap.

### BACKGROUND OF THE INVENTION

1. Field of the Invention

The present invention relates to a package structure and a wafer level package process, and more particularly, to a package structure capable of protecting devices on wafer surface and process for fabricating the same.

2. Description of the Prior Art

Currently, wafer level chip scale packages (WLCSP) have become one of the most popular packaging techniques, in which the wafer level chip scale packages are defined by having correspondingly equal or larger areas of the package structure than the area of the die. The area of the package structure is usually no larger than 25% of the die area. In general, the main difference between the wafer level chip scale package and the conventional package lies in the fact that the wafer level chip scale package first packages the wafer before the dicing process and performs a dicing process after the packaging process to form a plurality of packaging structures. This in comparison to the conventional package wherein first it dices the wafer to form a plurality of dies and performs a packaging process to each of the dies thereafter.

Since part of the wafer surface usually includes fragile structures, such as micro-electromechanical structures, special processes are often performed to protect the micro-electromechanical structures on the wafer surface during the packaging process of the wafer. Currently, protective caps made of metal or glass are commonly disposed on the fragile structures to protect the fragile structures from external damage, in which the fabrication of the protective caps can be divided into two categories. Preferably, one method of fabricating the protective caps involves dicing the wafer into a plurality of dies and fabricating protective caps on the surface of each die thereafter. However, this method is relatively complex and requires significantly long processing time. Hence, another wafer level package process has been introduced to fabricate the protective caps.

Please refer to FIG. 1 through FIG. 3. FIG. 1 through FIG. 3 are perspective diagrams showing a wafer level package process according to the prior art. As shown in FIG. 1, a substrate 12 is provided, in which the surface of the substrate 12 includes a plurality of fragile structures 16, such as micro-electromechanical structures. Next, a cap substrate 14 is provided, in which the surface of the cap substrate 14 includes a plurality of cavities 22, such that the cavities 22 are located corresponding to the fragile structures 16. Next, the cap substrate 14 is disposed on the substrate 12, in which the cavities 22 of the cap substrate 14 are corresponding to the fragile structures 16. Preferably, the cap substrate 14 also includes a plurality of bonding media 20 disposed on the periphery region surrounding the cavities 22, and a plurality of sealed rings 18 corresponding to the substrate 12, such that the bonding media 20 and the sealed rings 18 are utilized to bond the cap substrate 14 to the substrate 12.

As shown in FIG. 2, the cap substrate 14 and the substrate 12 are diced along the direction I to form a plurality of dies 30, in which the surface of each die 30 includes a protective cap 40 disposed on each of the fragile structures 16. Since the surface of the substrate 12 also includes a plurality of bonding pads 24 and the bonding pads 24 are covered by the protective caps 40, another dicing process must necessarily be performed along the direction 11 to dice the cap substrate 14 and expose the bonding pads 24 for facilitating electrical connection thereafter.

As a result, the two dicing processes utilized in the conventional packaging process will not only increase the possibility of misalignment, but also increase damage of the die and pollution caused by micro-particles. Hence, if the number of dicing process were to be reduced, damages resulted from the dicing process could be prevented and the yield of the package process could thereby be increased.

### SUMMARY OF THE INVENTION

It is therefore an objective of the present invention to provide a package structure and package process for protecting devices on the wafer surface to solve the above-mentioned problems.

According to the present invention, a wafer level package process includes: (a) providing a device substrate, wherein one surface of the device substrate includes a plurality of devices; (b) providing a cap substrate and forming a plurality of cavities on one surface of the cap substrate, wherein the location of each cavity is corresponding to the location of each device of the devices substrate; (c) forming a protective cap in each cavity by utilizing the cavity as a mold; (d) aligning each cavity of the cap substrate to each device of the device substrate and connecting the protective cap on the device substrate, such that each of the protective caps covers each device; and (e) removing the cap substrate from the protective cap.

It is another aspect of the present invention to provide a method of forming protective caps for protecting devices on a wafer surface, the method includes: (a) providing a cap substrate; (b) forming a plurality of cavities on one surface of the cap substrate, wherein the location of each cavity is corresponding to the location of the devices on the wafer surface; and (c) forming a protective cap in each cavity and forming a plurality of bonding media around the cavities.

It is another aspect of the present invention to provide a wafer level package, in which the wafer level package includes: a device substrate; a device disposed on one surface of the device substrate; a protective cap disposed above the device; a plurality of bonding media connected to the protective cap; and a plurality of sealed rings disposed between each bonding media and the device substrate.

It is another aspect of the present invention to provide a package structure, in which the package structure includes: a device substrate; at least a device disposed on one surface of the device substrate; a protective cap disposed on the device; a plurality of bonding media connected to the protective cap and the device substrate; and a molding compound covering the device substrate and the protective cap, in which the bottom of the molding compound includes a plurality of bumps, such that the external side of each of the bumps includes a metal film for electrically connecting to the device substrate.

By mass-producing the protective caps for devices on wafer surface and eliminating the extra dicing process for protective caps, the present invention is able to significantly reduce damages to the wafer and devices from the dicing process and thereby increase the overall yield.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 3 are perspective diagrams showing a wafer level package process according to the prior art.

FIG. 4 through FIG. 8 are perspective diagrams showing the means of fabricating a protective cap for devices on a wafer surface and a wafer level package process according to the present invention.

FIG. 9 and FIG. 10 are perspective diagrams showing the means of fabricating protective caps and bonding media according to another embodiment of the present invention.

FIG. 11 is a perspective diagram showing a package structure according to another embodiment of the present invention.

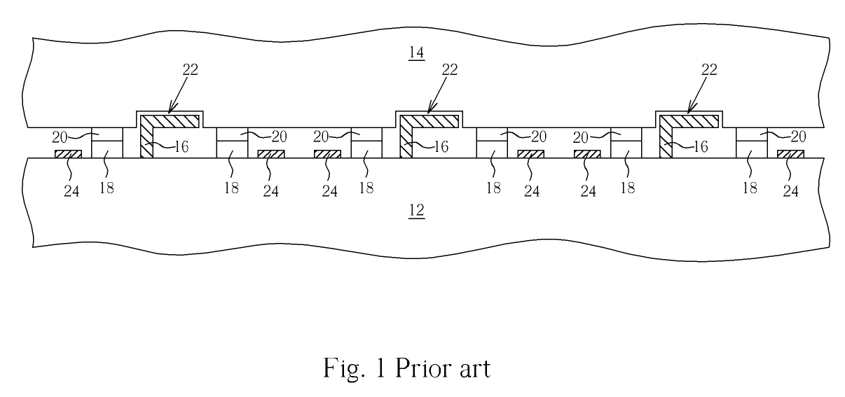

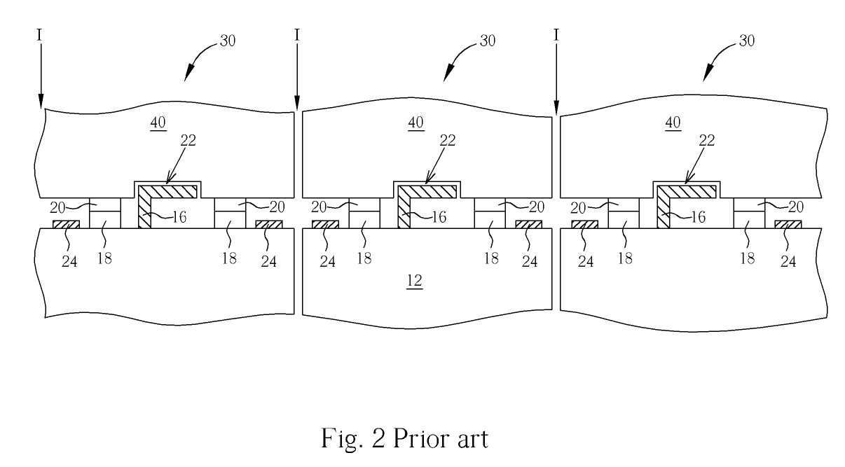

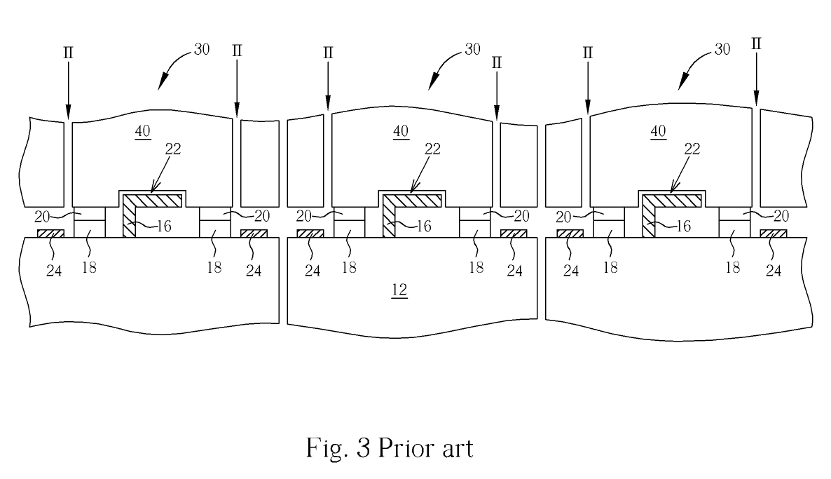

### DETAILED DESCRIPTION

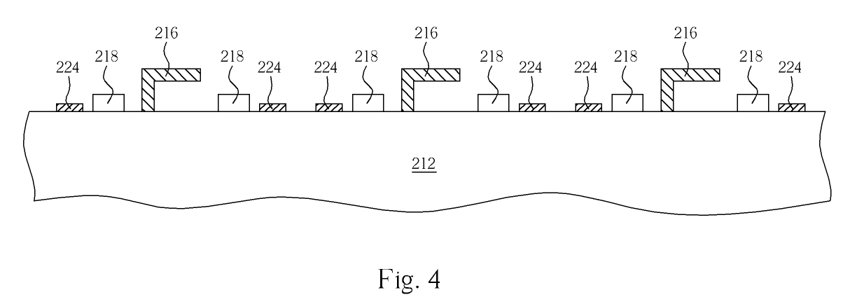

Please refer to FIG. 4 through FIG. 8. FIG. 4 through FIG. 8 are perspective diagrams showing the means of fabricating protective caps for devices on a wafer surface and a wafer level package process according to the present invention. As shown in FIG. 4, a device substrate 212 is provided, in which the surface of the device substrate 212 includes a plurality of devices 216. Preferably, the device substrate 212 is a semiconductor wafer, but by no means is the device substrate 212 limited to a semiconductor wafer, and the devices 216 are micro-electromechanical devices, light sensitive devices, or other devices. Additionally, a plurality of sealed rings 218 is disposed around the devices 216 for protecting the devices 216 in the later processes. Furthermore, the surface of the device substrate 212 also includes a plurality of bonding pads 224 for electrical connections. Since the devices 216 are usually delicate and fragile, a protective mechanism should be established for affording special protection to the devices 216.

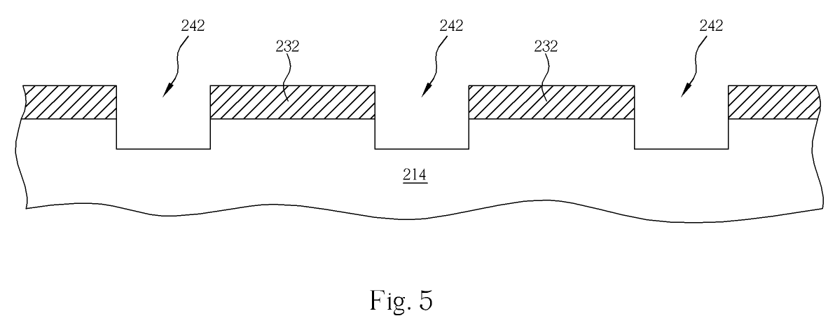

Please refer to FIG. 5. FIG. 5 illustrates a cap substrate 214 utilized for fabricating protective caps for protecting the devices 216. According to the preferred embodiment of the present invention, the cap substrate 214 is composed of metal, such as copper. Preferably, a patterned mask 232 is first disposed on the cap substrate 214, and an etching process is performed to etch the cap substrate 214 not covered by the patterned mask 232 to form a plurality of cavities 242 corresponding to each of the devices 216 on the device substrate 212.

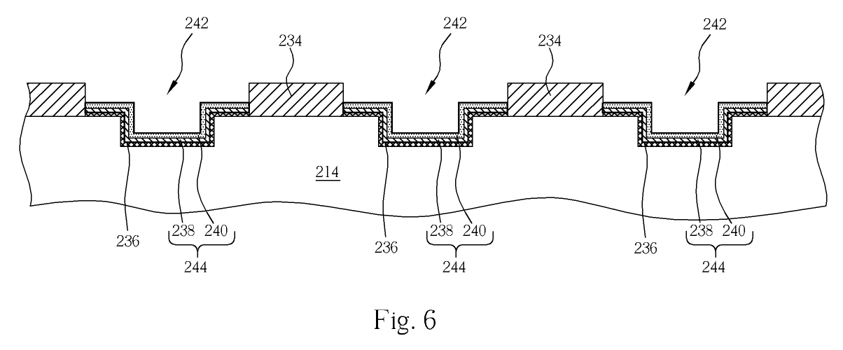

As shown in FIG. 6, the patterned mask 232 is removed after the formation of the cavities 242 and after the patterned mask 232 is removed, another patterned mask 234 is formed on the surface of the cap substrate 214, in which the patterned mask 234 exposes the cavities 242 and the surrounding area of the cavities 242. Next, a plating process, such as an electroplating process is performed to form a plurality of protective caps 236 composed of metal or non-metal on the exposed surface of the cap substrate 214. Since the protective caps 236 will be separated from the cap substrate 214 in the later processes, the material of the protective caps 236 should be selected accordingly. According to the preferred embodiment of the present invention, the cap substrate 214 is composed of copper and the protective caps 236 are composed of nickel, such that a higher selectivity can be achieved when the cap substrate 214 is removed from the protective caps 236 during the etching process. Subsequently, a plurality of bonding media 244 is formed on the protective caps 236. Preferably, each of the bonding media 244 is composed of a double layer structure having a tin layer 238 and a gold layer 240. Alternatively, the bonding media 244 can also be composed of different structures having different materials. The patterned mask 234 is removed thereafter.

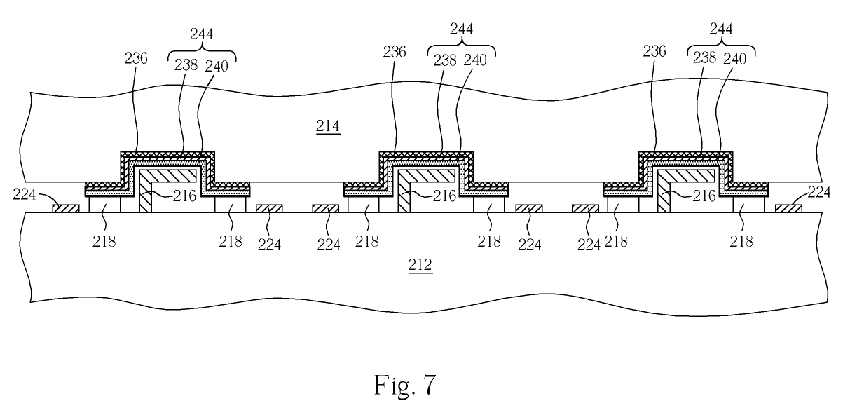

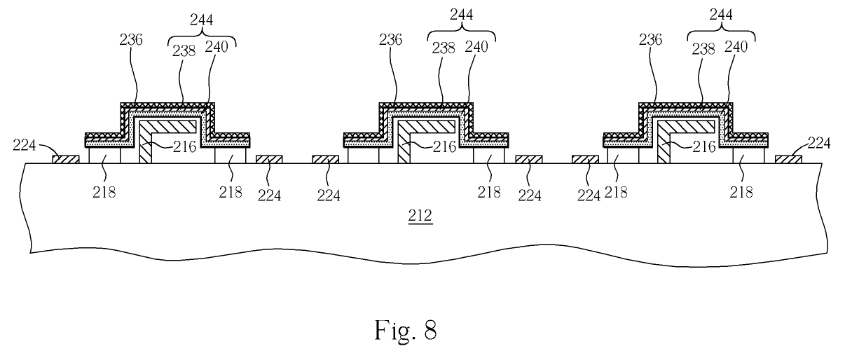

As shown in FIG. 7, the cavities 242 on the cap substrate 214 are aligned with the devices 216 on the device substrate 212, and the protective caps 236 are disposed on the device substrate 212, such that each of the devices 216 is covered by a protective cap 236 and the bonding media 244 are bonded to the sealed rings 218. Next, the cap substrate 214 is removed, as shown in FIG. 8. According to the preferred embodiment of the present invention, the cap substrate 214 is composed of copper and the protective caps 236 are composed of nickel. Since the selectivity between copper and nickel is substantially high, the present invention is able to utilize an etching process to remove the cap substrate 214 without damaging the protective caps 236. Alternatively, other processes can also be utilized to remove the cap substrate 214. Additionally, since the protective caps 236 only cover the devices 216 on the device substrate 212 but not the bonding pads 224, the electrical connection of the device substrate 212 will be not affected. As a result, the present invention requires only one dicing process to form a plurality of package structures, in which no extra dicing steps are needed for exposing the bonding pads 224 utilized for electrical connection afterwards.

As shown in FIG. 8, a package structure is also disclosed according to the preferred embodiment of the present invention. In contrast to the conventional method, each device 216 of the present invention is protected by a protective cap 236, in which the device substrate 212 already includes a plurality of non-connected protective caps 236 before the final dicing process. Additionally, in contrast to the conventional package structure wherein having only one corresponding protective cap to each die, each die of the present invention includes a plurality of devices 216 and each device 216 further includes a corresponding protective cap 236 after dicing the device substrate 212 into a plurality of dies via the dicing process. Furthermore, depending on different demands and the variety of the devices 216 utilized, the protective caps 236 can be composed of materials other than metal. For instance, if the devices 216 were light sensitive devices, the protective caps 236 can be composed of light sensitive materials such as glass or quartz for fabricating transparent protective caps.

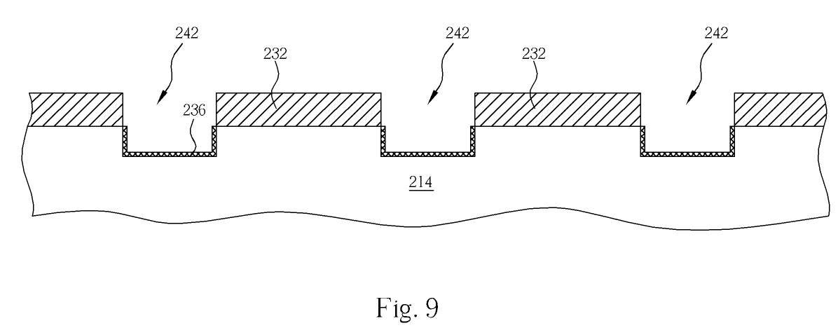

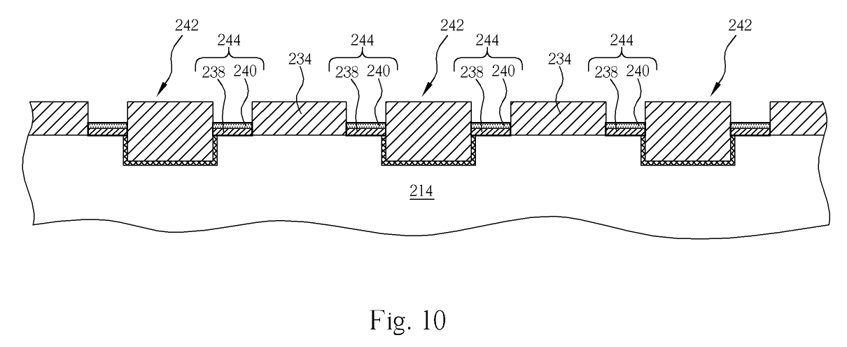

Preferably, the protective caps 236 are utilized to protect the devices 216, and the bonding media 244 are utilized to connect to the sealed rings 218 surrounding the devices 216 and fixed the protective caps 236 above the devices 216. Please refer to FIG. 9 and FIG. 10. FIG. 9 and FIG. 10 are perspective diagrams showing the means of fabricating protective caps and bonding media according to another embodiment of the present invention. As shown in FIG. 9, after the cavities 242 are formed, a plating process is performed to directly form the protective caps 236 in the cavities 242 while keeping the patterned mask 232. As shown in FIG. 10, after removing the patterned mask 232, another mask 234 is disposed on the cap substrate 214, in which the patterned mask 234 only exposes the surrounding of the cavities 242. Next, another plating process is performed to form a plurality of bonding media 244 around the cavities 244, in which the bonding media 244 are also composed of a tin layer 238 and a gold layer 240. The pattered mask 234 is removed thereafter.

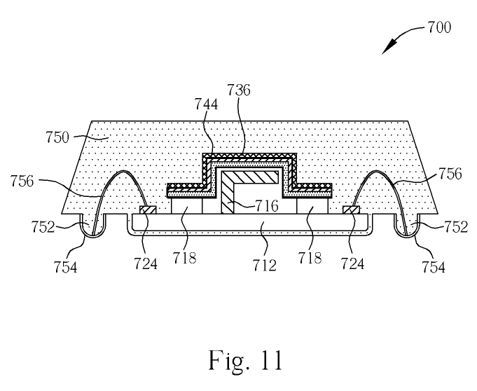

Please refer to FIG. 11. FIG. 11 is a perspective showing a package structure 700 according to another embodiment of the present invention, in which the package structure 700 is further processed from the package structure of FIG. 8. As shown in FIG. 11, the package structure 700 includes a device substrate 712, a plurality of devices 716 disposed on the surface of the device substrate 712, in which only one of the devices 716 is shown in FIG. 11, and a plurality of bonding pads 724 disposed on the surface of the device substrate 712. Preferably, a protective cap 736 and a plurality of bonding media 744 are formed on top of each device 716, in which the protective cap 736 and the bonding media 744 are composed of the layer structure described previously, and the bonding media 744 are also interconnected to the sealed rings 718 disposed on the device substrate 712. Additionally, the package structure 700 includes a molding compound 750 covering the device substrate 712 and the protective cap 736, in which the bottom of the molding compound 750 includes a plurality of bumps 752, such that the external surface of each bump 752 includes a metal film 754. Preferably, the inner surface of the metal film 754 is electrically connected to the device substrate 712 by utilizing wires 756 to connect to the solder pads 724 disposed on the device substrate 712, whereas the outer surface of the metal film 754 is utilized to connect to the exterior devices. Essentially, the package structure 700 can be fabricated by utilizing bump chip carrier (BCC) techniques or other fabrication processes.

In contrast to the conventional method of fabricating wafer level packages with fragile structures or other devices, the present invention is able to mass produce protective caps thereby increasing efficiency, and eliminate the heretofore required extra dicing process after disposing the protective caps on the device that needs to be protected. Therefore, the present invention is capable of significantly reducing damages to the wafer and devices thereon from the dicing process and therein increasing the overall yield.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer level package process comprising:
(a) providing a device substrate, wherein one surface of the device substrate comprises a plurality of devices and a sealed ring;
(b) providing a cap substrate and forming a plurality of cavities on one surface of the cap substrate, wherein the location of each cavity is corresponding to the location of each device of the devices substrate;
(c) forming a protective cap in each cavity by utilizing the cavity as a mold;
(d) aligning each cavity of the cap substrate to each device of the device substrate and connecting the protective cap on the sealed ring of the device substrate, such that each of the protective caps covers each device; and
(e) removing the cap substrate from the protective cap.

2. The wafer level package process of claim 1, wherein step (b) further comprises:
forming a patterned mask on the cap substrate;
etching the cap substrate not covered by the patterned mask for forming the cavities; and
removing the patterned mask.

3. The wafer level package process of claim 1, wherein step (c) further comprises forming a bonding media around each of the protective caps after the formation of the protective caps.

4. The wafer level package process of claim 3, wherein step (c) further comprises:
forming a patterned mask on the cap substrate, wherein the patterned mask exposes the cavities and the surrounding of the cavities;
performing a first plating process for forming the protective caps in and around the cavities; and
performing at least a second plating process for forming the bonding media in and around the cavities.

5. The wafer level package process of claim 4, wherein the cap substrate further comprises a first metal and the protective caps comprise a second metal, wherein the etching ratio of the first metal is higher than the etching ratio of the second metal.

6. The wafer level package process of claim 5, wherein step (e) comprises removing the first metal by utilizing an etching process.

7. The wafer level package process of claim 5, wherein the first metal comprises copper and the second metal comprises nickel.

8. The wafer level package process of claim 4, wherein each of the bonding media comprises a third metal and a fourth metal stacked over one another.

9. The wafer level package process of claim 8, wherein the third metal comprises tin and the fourth metal comprises gold.

10. A wafer level package comprising:
a device substrate;
a device disposed on one surface of the device substrate;
a protective cap disposed above the device;
a plurality of bonding media connected to the protective cap; and
a plurality of sealed rings disposed between each bonding media and the device substrate.

11. The wafer level package of claim 10, wherein the protective cap comprises a metal protective cap.

12. The wafer level package of claim 10, wherein the bonding media comprise metal bonding media.

13. The wafer level package of claim 10, wherein the device substrate further comprises a plurality of bonding pads disposed over the surface of the device substrate, wherein the bonding pads are not covered by the protective caps.

14. The wafer level package of claim 10, wherein the protective cap comprises a light-penetrating protective cap.

15. The wafer level package of claim 10, wherein the device comprise a light sensitive device.
